(19) United States
(12) Patent Application Publication
(10) Pub. No.: US 2025/0231219 A1
(43) Pub. Date: Jul. 17, 2025

(54) TESTING METHOD, DEVICE UNDER TEST, PROBE CARD AND PROBE SYSTEM FOR MICRO-BUMP TEST

(71) Applicant: MPI CORPORATION, CHU-PEI CITY (TW)

(72) Inventors: CHIN-TIEN YANG, CHU-PEI CITY (TW); TSUNG-YI CHEN, CHU-PEI CITY (TW); HUI-PIN YANG, CHU-PEI CITY (TW)

(73) Assignee: MPI CORPORATION, CHU-PEI CITY (TW)

(21) Appl. No.: 19/020,810

(22) Filed: Jan. 14, 2025

Related U.S. Application Data
(60) Provisional application No. 63/621,249, filed on Jan. 16, 2024.

(51) Int. Cl. G01R 1/073; G01R 31/28

(52) U.S. Cl. CPC G01R 1/07357; G01R 1/07342; G01R 1/07378; G01R 31/2886

(57) ABSTRACT

A testing method for a micro-bump test includes providing a device under test arranged with a first bump unit for transmitting the power or ground signal and a second bump unit for transmitting the test signal, the first and second bump units both having grouping micro-bumps, or one of them only having a single relatively larger bump, the micro-bumps of the second bump unit including a selected micro-bump and a dummy micro-bump; providing a test apparatus including a chuck and a probe card whose probes' body portions are substantially the same in size; placing the device under test on the chuck, and testing it by the probes. The probe card is lowered in manufacturing difficulty, cost and difficulty in usage on a testing machine, and prevented from different probe wear loss and the resulting poor probe planarity problem. The device under test is prevented from too complicated design.

### BACKGROUND OF THE INVENTION

### 1. Field of the Invention

The present invention relates generally to micro-bump testing technology and more particularly, to a testing method, a device under test, a probe card and a probe system for a micro-bump test.

### 2. Description of the Related Art

As the development of system in package technology trends more and more important, 2.5D/3D stacking package technology receives more and more attention in the electronic product market. Wherein, chiplets or interposers adopt micro-bumps for 2.5D/3D stacking package, so the need to test micro-bumps trends upwards.

Each device under test has many micro-bumps, and the micro-bumps have very small size (about 10-30 μm in diameter) and pitch (about 25-60 μm). If the test is performed by directly using probes of a probe card to contact the micro-bumps, the probe card will be very difficult in manufacture and very expensive, and also difficult in practical use on a machine for testing. Therefore, the testing manner using sacrificial pads (or called schemed pads) is mainly adopted presently, wherein additional pads with relatively larger pitch, e.g. 80-180 μm, are provided for being electrically contacted by the probes. However, this testing manner not only wastes the useful area on dies, but also unfavorably affects high-frequency/high-speed tests.

In the industry, it is presently tried to design additional sacrificial bumps (or called schemed bumps) for being electrically contacted by the probes, wherein bumps with relatively larger size and pitch are used for lowering the difficulty of manufacturing the probe card and using the probe card on the machine for testing. However, this manner also wastes the useful area on dies, and the design is limited by trace space and amount.

At present, another testing manner called selected bump is also tried in the industry, wherein only some micro-bumps are chosen to be tested, but not all the micro-bumps are tested. In this testing manner, although the probe card can have relatively larger pitch between the probes, but it still tests the bumps with very small size, thereby having certain difficulty. Besides, this testing manner will cause further complication to the design of the device under test, so it is hard to be adopted comprehensively.

### SUMMARY OF THE INVENTION

The micro-bumps in each device under test are mostly power micro-bumps for transmitting the power signal and ground micro-bumps for transmitting the ground signal. Therefore, the testing manner of using a single probe to contact a plurality of power micro-bumps and/or ground micro-bumps can be adopted, such that the amount of the probes of the probe card is highly reduced and thereby the cost of the probe card is lowered. However, except for power micro-bumps and/or ground micro-bumps, each device under test also has relatively fewer testing micro-bumps for the input and output of test signals. If the single probe still contacts the single testing micro-bump, an arrangement of hybrid probes should be adopted. That is, there are two or more probe types in a same probe card, so that the probe contacting a plurality of power micro-bumps and/or ground micro-bumps generates relatively larger contact force, and the probe contacting a single testing micro-bump generates relatively smaller contact force. However, in the condition that there are at least two different probe types in a same probe card, the probes of different probe types are different in wear loss, so the probe card, after used for a period of time, is prone to the problem of poor probe planarity, which means the terminal ends of the probes are not located on a same horizontal plane.

The present invention has been accomplished in view of the above-noted circumstances. It is an objective of the present invention to provide a testing method, a device under test, a probe card and a probe system for a micro-bump test, which can lower the difficulty of manufacturing the probe card, the cost of the probe card and the difficulty of using the probe card on the machine for testing, and can prevent the device under test from too complicated design, and can avoid using hybrid probes so as to avoid the poor probe planarity problem that may be caused by the difference in wear loss between the probes of different probe types.

To attain the above objective, the present invention provides a testing method for a micro-bump test, which uses a probe card in a probe system to test a device under test having a plurality of micro-bumps. The testing method includes the steps of:
providing the device under test, the device under test including a first bump unit for transmitting a first signal and a second bump unit for transmitting a second signal, the first signal being one of a power signal and a ground signal, the second signal being a test signal different from the power signal and the ground signal, the device under test having one of the following three arrangements that:
the device under test is configured in a way that the first bump unit includes a plurality of first micro-bumps grouping together, the second bump unit includes a plurality of second micro-bumps grouping together, the amount of the first micro-bumps of the first bump unit is the same with the amount of the second micro-bumps of the second bump unit, the first micro-bumps are all arranged for transmitting the first signal, and the second micro-bumps include at least one selected micro-bump arranged for transmitting the second signal and at least one dummy micro-bump unable to transmit the second signal out of the second bump unit;
the device under test is configured in a way that the first bump unit includes a plurality of first micro-bumps grouping together, the second bump unit only includes a single second bump, the area of the second bump is larger than the area of a single first micro-bump, the first micro-bumps are all arranged for transmitting the first signal, and the second bump is arranged for transmitting the second signal; and
the device under test is configured in a way that the first bump unit only includes a single first bump, the second bump unit includes a plurality of second micro-bumps grouping together, the area of the first bump is larger than the area of a single second micro-bump, the first bump is arranged for transmitting the first signal, and the second micro-bumps include at least one selected micro-bump arranged for transmitting the second signal and at least one dummy micro-bump unable to transmit the second signal out of the second bump unit;
providing a test apparatus, the test apparatus including a chuck and the probe card, the probe card including a plurality of probes, each of the probes including a head portion located at an end of the probe for contacting the device under test, a tail portion located at the other end of the probe, and a body portion located between the head portion and the tail portion, the body portions of the plurality of probes being substantially the same in size; and
placing the device under test on the chuck of the test apparatus, and testing the device under test by using the probes of the probe card to contact the device under test, wherein during the device under test being tested, the first bump unit is contacted by only one of the plurality of probes, and the second bump unit is contacted by only another one of the plurality of probes.

The present invention provides a device under test for a micro-bump test, which is the device under test as provided in the above-described testing method.

As a result, on the device under test, the power micro-bumps for transmitting the power signal and the ground micro-bumps for transmitting the ground signal can be arranged according to the above-described arrangement of the first bump unit. That is, a plurality of power micro-bumps or ground micro-bumps serve as first micro-bumps which group together into a first bump unit, enabling a same probe to contact a plurality of first micro-bumps of a same first bump unit at the same time to provide the power signal or ground signal to the circuits corresponding to the first micro-bumps respectively. Alternatively, the plurality of first micro-bumps may be replaced by a relatively larger first bump for a probe to contact the first bump to provide the power signal or ground signal to the circuits respectively corresponding to the former plurality of first micro-bumps. As to the testing micro-bumps on the device under test for transmitting test signals, they are relatively fewer in amount, so they can be arranged according to the above-described arrangement of the second bump unit. That is, at a place near the testing micro-bump for actually transmitting the test signal, i.e. selected micro-bump, one or more extra micro-bumps, i.e. dummy micro-bumps, may be added so that they group together into a second bump unit for a same probe to contact a plurality of second micro-bumps of a same second bump unit at the same time, including the selected micro-bump and the dummy micro-bump, so as to provide the test signal to the circuit corresponding to the selected micro-bump. In this way, the dummy micro-bump bears a part of the probe contact force to make the probing pressure received by the selected micro-bump the same with the probing pressure received by the first micro-bump or the first bump. Alternatively, no dummy micro-bump may be provided, but the selected micro-bump is replaced by a relatively larger second bump to make the probing pressure received by the second bump the same with the probing pressure received by the first micro-bump. As a result, the probe card can be arranged with relatively fewer probes, and the probes can be provided therebetween with relatively larger pitch. Besides, each probe is arranged to contact a plurality of micro-bumps or a single relatively larger bump. Therefore, the difficulty of manufacturing the probe card, the cost of the probe card and the difficulty of using the probe card on a machine for testing are relatively lower, and the design of the device under test is not too complicated. In addition, the body portions of the probes of the probe card are substantially the same in size, which means the body portions of the probes are substantially the same in structural type, and/or substantially the same in length, width and thickness, and/or substantially the same in cross-sectional area. For example, the body portions of the probes may be substantially the same in all the aspects of structural type, length, width, thickness and cross-sectional area. In this way, the probes will generate substantially the same probe contact force and wear loss. Of course, the probes may not only have the same body portions, but also be substantially the same in size of the head portion and/or the tail portion. However, the head portion and the tail portion have relatively less affection on the probe contact force. In other words, the present invention can avoid using hybrid probes, so as to avoid the poor probe planarity problem that may be caused by the difference in wear loss between the probes of different probe types. Wherein, to avoid using hybrid probes means all the adopted probes are the same probes, or at least the body portions of all the adopted probes are substantially the same in size. The aforementioned the same probes are entirely, including the head portion, the tail portion and the body portion, substantially the same in structural type, and/or substantially the same in length, width and thickness, and/or substantially the same in cross-sectional area. For example, the probes may be substantially the same in all the aspects of structural type, length, width, thickness and cross-sectional area. Although it is described above that the micro-bumps receive the same probing pressure, it can be also understood by those skilled in this technical field as the probes apply the same contact force to the micro-bumps.

Preferably, the head portions of the plurality of probes have a substantially same cross-sectional area. As a result, the head portions of the plurality of probes will apply the same contact force to the first bump unit and the second bump unit on the device under test, and will be the same in wear loss, which prevents the probe card from having the poor probe planarity problem after being used for a period of time.

Preferably, each probe is one of a straight probe and a buckling probe. As a result, the present invention suits with vertical probes. The vertical probe extends approximately along the vertical axis, but the body portion thereof is curved and thereby can be slightly elastically deformed when the probe contacts the device under test. The vertical probe may be the straight probe which is shaped as a straight line when the manufacture thereof is accomplished. The body portion thereof is curved by the offset between the dies of the probe seat after the probe is installed in the probe seat. Alternatively, the vertical probe may be the buckling probe (usually called Cobra) which has buckling shape when the manufacture thereof is accomplished. The present invention may adopt straight probes or buckling probes according to the usage requirement.

Preferably, the device under test is configured in a way that when the first bump unit and the second bump unit are contacted by the head portions of the probes, the first bump unit and the second bump unit receive a substantially same probing pressure. For example, in the condition that the first bump unit includes a plurality of first micro-bumps and the second bump unit includes a plurality of second micro-bumps, the first micro-bumps and the second micro-bumps being the same in amount makes the first bump unit and the second bump unit have equal areas to bear the same probe contact force applied by the probes, such that the first bump unit and the second bump unit receive the same probing pressure. Alternatively, in the condition that one of the first and second bump units includes a plurality of micro-bumps and the other includes a single relatively larger bump, the amount, interval and/or area of the micro-bumps can be designed in coordination with the area of the single relatively larger bump to make the first bump unit and the second bump unit receive the same probing pressure. As a result, the probe card can generate consistent probing performance, and can be prevented from different wear loss between the probes and the resulting poor probe planarity problem.

Preferably, the first bump unit has a first upper surface for being contacted by the probe of the probe card. The second bump unit has a second upper surface for being contacted by the probe of the probe card. The first upper surface and the second upper surface are substantially located on a same horizontal plane. As a result, no matter the first bump unit or the second bump unit includes a plurality of micro-bumps or only includes a single relatively larger bump, the upper surfaces of the first and second bump units are substantially located on a same horizontal plane, which enables the head portions of the probes to simultaneously contact the bump and/or micro-bumps required to be contacted thereby, so as to generate consistent probing performance, and avoid different wear loss between the probes and the resulting poor probe planarity problem.

Preferably, the dummy micro-bump and the selected micro-bump of the second bump unit are substantially the same in size. As a result, because the micro-bumps on the device under test are mostly substantially the same in size, when the extra micro-bump, i.e. dummy micro-bump, is added near the testing micro-bump, i.e. selected micro-bump, making the dummy micro-bump and the selected micro-bump substantially the same in size can maintain the uniformity of the size of the micro-bumps on the device under test. That makes the design relatively simpler, facilitates the positional arrangement of the micro-bumps, and makes the probe contact force shared relatively more evenly, thereby beneficial for generating consistent probing performance.

Preferably, the dummy micro-bump and the selected micro-bump of the second bump unit are electrically disconnected from each other. In other words, the dummy micro-bump is provided only to share the probe contact force with the selected micro-bump, but doesn't have any signal transmitting function. In this way, the device under test has relatively fewer circuits, thereby relatively easier to design and manufacture. However, the dummy micro-bump and the selected micro-bump may be electrically connected with each other, so that the dummy micro-bump can receive the test signal transmitted from the probe. Although the dummy micro-bump cannot transmit the test signal out of its belonging second bump unit, but the dummy micro-bump can transmit the test signal to the selected micro-bump of its belonging second bump unit, which can improve the test signal transmitting stability of the second bump unit.

Preferably, the probes of the probe card are arranged in a way that when contacting the device under test to test the device under test, the plurality of probes provide a substantially same probe contact force, thereby making the bumps and micro-bumps on the device under test receive the same probing pressure, and avoiding different wear loss between the probes and the resulting poor probe planarity problem.

Preferably, the head portions of the plurality of probes have substantially a same cross-sectional shape, thereby generating consistent probing performance.

More preferably, the cross-sectional shape of the head portions of the plurality of probes is one of a circle and a rectangle, thereby beneficial for contacting the bumps and/or micro-bumps on the device under test.

Preferably, the body portion of the probe includes at least one slot. The slot penetrates through the body portion along a first horizontal axis so that the body portion is defined with at least two arm sections by the at least one slot. The at least two arm sections are separated from each other along a second horizontal axis. The body portion is curved along the second horizontal axis.

As a result, the slot can weaken the rigidity of the body portion, so as to lower the contact force applied by the probe to the device under test, thereby preventing the probe contact force from being so larger as to damage the bumps and/or micro-bumps of the device under test. Particularly, for the testing requirement of high-frequency or high-speed, the adopted probes are usually relatively shorter in length, which can obtain great electrically transmitting performance. However, the probe relatively shorter in length is relatively higher in rigidity and contact force. In such condition, the probe can be provided with the slot to lower the probe contact force. Besides, the slot also improves the elasticity of the body portion, thereby ensuring the elastically deformed effect of the body portion being curved along the second horizontal axis.

Preferably, the plurality of probes include a first probe and a second probe. The cross-sectional area of the head portion of the second probe is smaller than the cross-sectional area of the head portion of the first probe. During the device under test being tested, the head portion of the first probe contacts the plurality of first micro-bumps at the same time, and the head portion of the second probe contacts only one second micro-bump.

As a result, even though the head portion of the second probe is manufactured with the size for contacting only one second micro-bump, the first and second probes still satisfy the aforementioned condition that their body portions are substantially the same in size, so that the first and second probes still generate substantially the same probe contact force, thereby substantially the same in wear loss and further avoiding the poor probe planarity problem.

More preferably, the projected area of the body portion of the second probe covers the plurality of second micro-bumps.

As a result, even though the head portions of the first and second probes contact different amounts of micro-bumps, the projected areas of the body portions of the first and second probes still correspond to the same amount of micro-bumps. Therefore, the arrangement of the second micro-bumps can be the same with the arrangement of the first micro-bumps, such that the micro-bumps of the device under test still maintain a neat arrangement, such as being arranged in a matrix. In this way, the design of the micro-bumps of the device under test is simple and uniform.

Preferably, in the arrangement of the device under test, the plurality of first micro-bumps are four first micro-bumps arranged in a 2×2 array, and the plurality of second micro-bumps are four second micro-bumps arranged in a 2×2 array.

As a result, when the four first micro-bumps of the first bump unit are contacted by the head portion of a probe and the four second micro-bumps of the second bump unit are contacted by the head portion of another probe, all the first and second micro-bumps are located correspondingly to the corners of the head portions, which are also referred to as corner micro-bumps hereinafter. In other words, there is no first or second micro-bump located correspondingly to the central section of the head portion. In the 2×2 array, the positions of the corner micro-bumps are relatively more explicit and facilitate the positioning. The design of the probe can be fine-tuned and optimized for corners in particular, especially in the condition that there are only corner micro-bumps required to be tested, which can improve the accuracy of the contact between the probes and the micro-bumps. Besides, in the same area, the micro-bumps in the 2×2 array have relatively larger distance therebetween when compared with the arrangement with more micro-bumps, such as 3×3 array. Therefore, in the 2×2 array, the risk of signal interference between the adjacent micro-bumps may be reduced. For accurate tests, this arrangement helps improving the testing accuracy, especially in the condition that the test signal is sensitive to the interference between the adjacent micro-bumps.

The present invention provides a probe card for a micro-bump test, which is applied in a probe system to test a device under test having a plurality of micro-bumps. The probe card includes a main circuit board, a space transformer, and a probe head. The probe head and the main circuit board are disposed on two opposite sides of the space transformer. The probe head includes at least one die unit and a plurality of probes. The die unit is provided with a plurality of guiding holes. The probes are slidably inserted in the guiding holes. Each probe includes a head portion located at an end of the probe for contacting the device under test, a tail portion located at the other end of the probe, and a body portion located between the head portion and the tail portion. The body portions of the plurality of probes are substantially the same in size. The tail portions of the probes are electrically connected to the space transformer. Wherein, the device under test is the device under test as described above. When the device under test is tested by the probe card, the device under test is placed on a chuck of the probe system, the first bump unit is contacted by only one of the plurality of probes, and the second bump unit is contacted by only another one of the plurality of probes.

As a result, the probe card is applicable to the above-described testing method, and can attain the above-described effects. Such probe card is lowered in manufacturing difficulty, cost and the difficulty of being used on a machine for testing, and can prevent the device under test from too complicated design, and avoid using hybrid probes, thereby prevented from the poor probe planarity problem that may be caused by difference in wear loss between the probes of different probe types.

The present invention provides a probe system for a micro-bump test, which is configured to test a device under test having a plurality of micro-bumps. The probe system includes a chuck configured to support the device under test, a probe card as described above, an imaging device, and a signal generation and analysis device. The imaging device is configured to collect the optical image of at least a region of the probe system. The signal generation and analysis device is configured to supply a test signal to the device under test and/or receive a resultant signal from the device under test.

As a result, according to the optical image obtained by the imaging device, the relative orientation between the head portions of the probes of the probe card and the chuck can be optionally changed to enable the head portions of the probes to contact the bumps and/or micro-bumps of the device under test. Through the probe card, the signal generation and analysis device provides the test signal to the device under test and/or receives the resultant signal from the device under test. Such probe system is applicable to perform the above-described testing method, so as to test the above-described device under test and attain the above-described effects.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

FIG. 1 is a schematic view of a probe system for a micro-bump test and a wafer according to a first preferred embodiment of the present invention.

FIG. 2 and FIG. 3 are schematic sectional views of a probe head of a probe card of the probe system, showing the configurations adopting straight probes and buckling probes respectively.

FIG. 4 is a schematic perspective view showing a device under test on the wafer and the corresponding probes.

FIG. 5 is a schematic top view of the device under test.

FIG. 6 is a schematic front view of the device under test and the corresponding probes.

FIG. 7 is a schematic top view of a device under test for a micro-bump test according to a second preferred embodiment of the present invention.

FIG. 8 is a schematic front view of the device under test and the corresponding probes.

FIG. 9 is a schematic top view of a device under test for a micro-bump test according to a third preferred embodiment of the present invention.

FIG. 10 is a schematic front view of the device under test and the corresponding probes.

FIG. 11 is a schematic sectional view of a probe head of a probe card for a micro-bump test according to a fourth preferred embodiment of the present invention.

FIG. 12 is a schematic front view of the device under test and the corresponding probes according to the fourth preferred embodiment of the present invention.

FIG. 13 is a schematic top view of the device under test, also schematically showing the projected areas of the body portions and head portions of the associated first and second probes.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

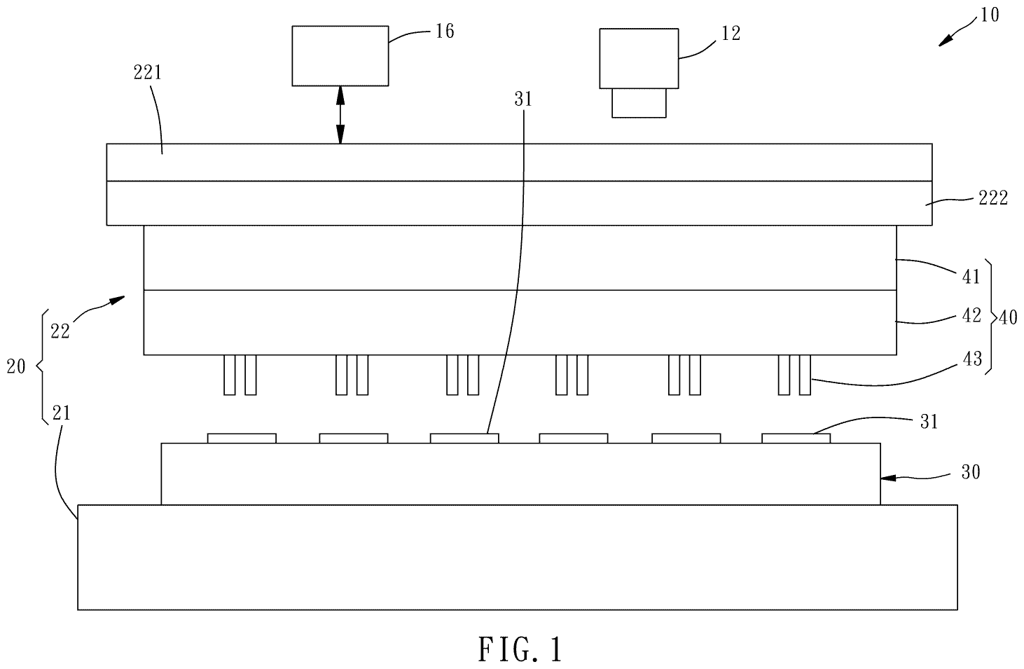

Referring to FIG. 1, a probe system 10 for a micro-bump test according to a first preferred embodiment of the present invention includes a test apparatus 20, an imaging device 12, and a signal generation and analysis device 16. The test apparatus 20 includes a chuck 21 and a probe card 22. A wafer 30 is placed on the chuck 21, and the wafer 30 is formed thereon with a plurality of devices under test 31.

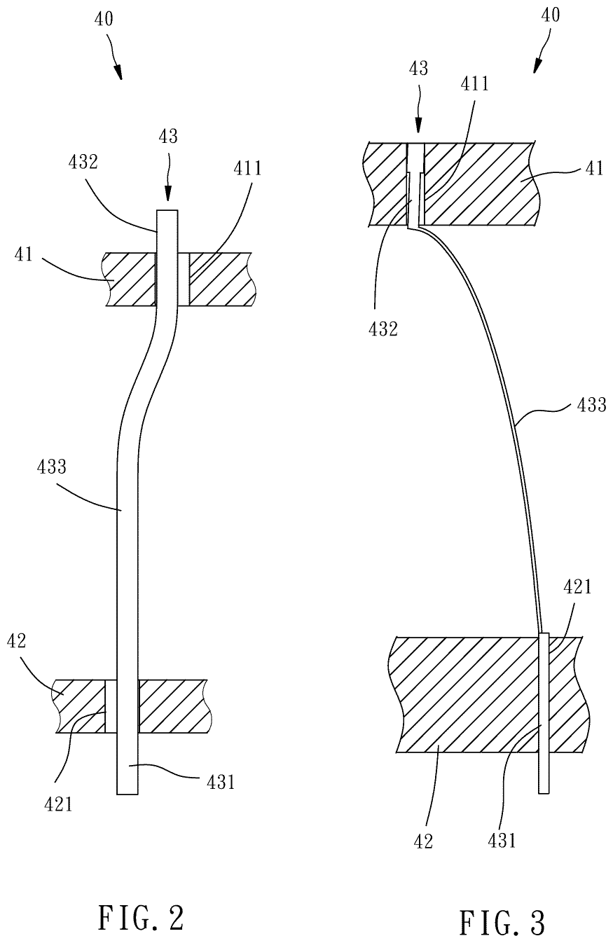

The probe card 22 includes a main circuit board 221, a space transformer 222, and a probe head 40. The main circuit board 221 and the probe head 40 are disposed on two opposite sides of the space transformer 222. The probe head 40 includes an upper die unit 41, a lower die unit 42, and a plurality of probes 43 inserted in the upper and lower die units 41, 42. Referring to FIG. 2 and FIG. 3, the upper die unit 41 includes a plurality of upper guiding holes 411. The lower die unit 42 includes a plurality of lower guiding holes 421. The probe 43 is slidably inserted in the upper and lower guiding holes 411, 421. For the simplification of the figures and the convenience of illustration, only one upper guiding hole 411, one lower guiding hole 421 and one probe 43 are shown in FIG. 2 and FIG. 3. In FIG. 2 and FIG. 3, two kinds of probes different in structural type are shown respectively, which are selectable for use according to different usage requirements, not both disposed in a same probe card 22 at the same time. The probe 43 includes a head portion 431 located at an end of the probe 43, a tail portion 432 located at the other end of the probe 43, and a body portion 433 located between the head portion 431 and the tail portion 432. The head portion 431 is inserted in the lower guiding hole 421 for contacting the device under test 31. The tail portion 432 is inserted in the upper guiding hole 411 for being abutted against a pad on the lower surface of the space transformer 222 and thereby electrically connected to the space transformer 222, so that the probe 43 is electrically connected to the signal generation and analysis device 16 through the space transformer 222 and the main circuit board 221. Specifically speaking, the optical image of at least a region of the probe system 10 is captured by the imaging device 12, so that the relative orientation between the head portions 431 of the probes 43 of the probe card 22 and the chuck 21 can be obtained. Accordingly, the aforementioned relative orientation can be optionally changed to enable the head portions 431 of the probes 43 to contact the bumps and/or micro-bumps of the device under test 31 (specified hereinafter). Through the probe card 22, the signal generation and analysis device 16 provides the test signal to the device under test 31 and/or receives the resultant signal from the device under test 31, so as to test the device under test 31. The body portion 433 is located between the upper and lower die units 41, 42, and the body portion 433 is usually configured being able to slightly elastically deform when the probe 43 contacts the device under test 31, which will be specified hereinafter.

According to some embodiments of the present invention, such as those shown in FIG. 2 and FIG. 3, each probe 43 included in the probe head 40 may be the probe called buckling probe (or buckling beam) in this field. That is, the body portion 433 of the probe 43 may have constant transverse cross-sections among the overall length thereof. For example, the shape of the transverse cross-sections is a substantial rectangle, and preferably a square or a rectangle. The body portion 433 is adapted to curve and/or stretch substantially at the center thereof, so as to deform during the process of testing the device under test 31. However, in some other embodiments, the body portion 433 of each probe 43 is unnecessary to have constant transverse cross-sections among the overall length thereof.

In this specification, the term ‘substantial rectangle’ refers to the rectangular shape and other practical results that may be produced under the intention of manufacturing the body portion with rectangular transverse cross-sections, such as trapezoid. More specifically speaking, those skilled in the technical field of the present invention should understand that even though the equipment for manufacturing the probe 43 is assigned to manufacture the probe having rectangular transverse cross-sections, the transverse cross-sections of the actually produced probe 43 may still have a certain tolerance or manufacturing error so that in some embodiments the shape of the transverse cross-sections of the body portion 433 of the probe 43 is not the geometrically perfect rectangle.

The applicable probes 43 for the present invention may at least include the straight probe as shown in FIG. 2 or the buckling probe (or called pre-curved probe) as shown in FIG. 3. The straight probe refers to the probe 43 shaped as a straight line when the manufacture thereof is accomplished. The body portion 433 thereof is curved by the transverse offset between the upper and lower die units 41, 42 after the probe 43 is installed in the upper and lower die units 41, 42. The buckling probe refers to the probe 43 which has the buckling shape when the manufacture thereof is accomplished. That means the body portion 433 thereof is originally curved in shape, so it doesn't need to be curved by the offset between the upper and lower die units 41, 42. More specifically speaking, the straight probe may be, for example, a forming wire (also referred to as FW) or a microelectromechanical systems (MEMS) wire (also referred to as MW). The pre-curved probe may be, for example, a cobra probe or a MEMS body pre-curved forming probe, and so on.

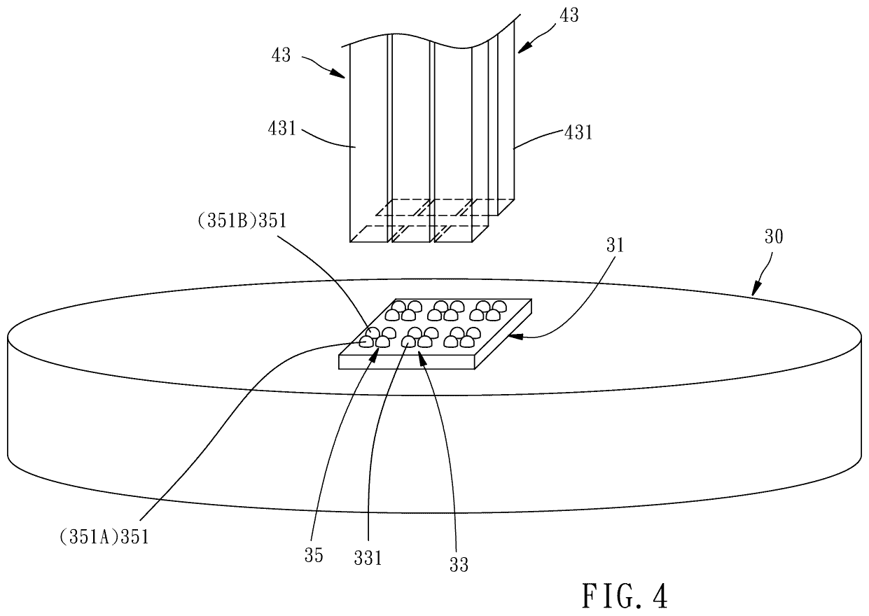

As shown in FIG. 4, the head portion 431 of each probe 43 is configured to be abutted against the bump (specified hereinafter) of the device under test 31 integrated in the semiconductor wafer 30. The head portions 431 of only six probes 43 are schematically shown in FIG. 4. When each probe 43 is applied with a load, such as the force received by the bottom end of each probe 43 contacting the corresponding bump during the device under test 31 being tested, the body portion 433 of each probe 43 can be deflected and deformed in an arc manner along its longitudinal extending axis.

It should be mentioned here that when the probe 43 is in use to test the device under test 31, the head portion 431 of the probe 43 and the bump of the device under test 31 contact each other, and then relatively displace for a distance called overdrive (also referred to as OD) or called overtravel (also referred to as OT) to further approach each other. That makes the body portion 433 of the probe 43 compressed and deformed in a buckling manner, and makes the head portion 431 of the probe 43 pressed and contact the bump of the device under test 31. During this process, the force applied by the probe 43 to the bump of the device under test 31 is defined as the probe contact force in the present invention. The larger the probe contact force, the smaller the contact resistance between the probe 43 and the bump of the device under test 31. The probe contact force is measured by applying the OD/OT to the probe 43 to deform the body portion 433 thereof in a buckling manner, and meanwhile measuring the value of the force applied by the probe 43 on a force sensor.

Further speaking, the probe contact force includes a probe deformation force and a probe friction. The probe deformation force refers to the force required for the elastic deformation of the probe 43 in the process of the aforementioned overdrive. The probe deformation force depends on many factors, such as the material properties of the probe 43 (e.g. Young's modulus, elastic modulus), the final geometric shape and size of the probe 43 (e.g. length, thickness, width, and so on). The probe friction refers to the friction applied to the probe 43 from the inner wall of the aforementioned upper guiding hole 411 and/or the inner wall of the aforementioned lower guiding hole 421. The probe contact force can steadily push the tail portion 432 of the probe 43 to be abutted against the pad of the aforementioned space transformer 222 (also referred to as ST), and then buckle the body portion 433 of the probe 43. That can make the probe 43 and the bump of the device under test 31 electrically connected with each other, thereby making the bump of the device under test 31 electrically connected to the testing machine through the probe 43.

The testing method provided by the present invention will be described hereinafter, and the arrangement of the bumps of the device under test 31 will be further described at the same time. Referring to FIG. 4 to FIG. 6, the testing method includes the following step a) to step c).
a) Provide the device under test 31. The device under test 31 has a die connecting surface, and a micro-bump array composed of a plurality of micro-bumps on the die connecting surface, wherein the micro-bump array includes a first bump unit 33 for transmitting a first signal, and a second bump unit 35 for transmitting a second signal. The first signal is one of a power signal (e.g. chip package power busbar PWR) and a ground signal (e.g. chip package ground busbar GND). The second signal is a test signal (e.g. chip package data signal busbar I/O) different from the power signal and the ground signal.

Further speaking, the device under test 31 in this embodiment is arranged in a way that the first bump unit 33 includes four first micro-bumps 331 grouping together, which are arranged in a 2×2 array, and the second bump unit 35 includes four second micro-bumps 351 grouping together, which are arranged in a 2×2 array. The amount of the first micro-bumps 331 of the first bump unit 33 is the same with the amount of the second micro-bumps 351 of the second bump unit 35. The amount can be any plural number, such as two, three, four or more. The first micro-bumps 331 are all arranged for transmitting the first signal, which means the four first micro-bumps 331 transmit the power signal together or transmit the ground signal together. The second micro-bumps 351 include at least one selected micro-bump 351A arranged for transmitting the second signal, and at least one dummy micro-bump 351B unable to transmit the second signal out of the second bump unit 35. In this embodiment, the four second micro-bumps 351 include only one selected micro-bump 351A, and the other three are all dummy micro-bumps 351B.

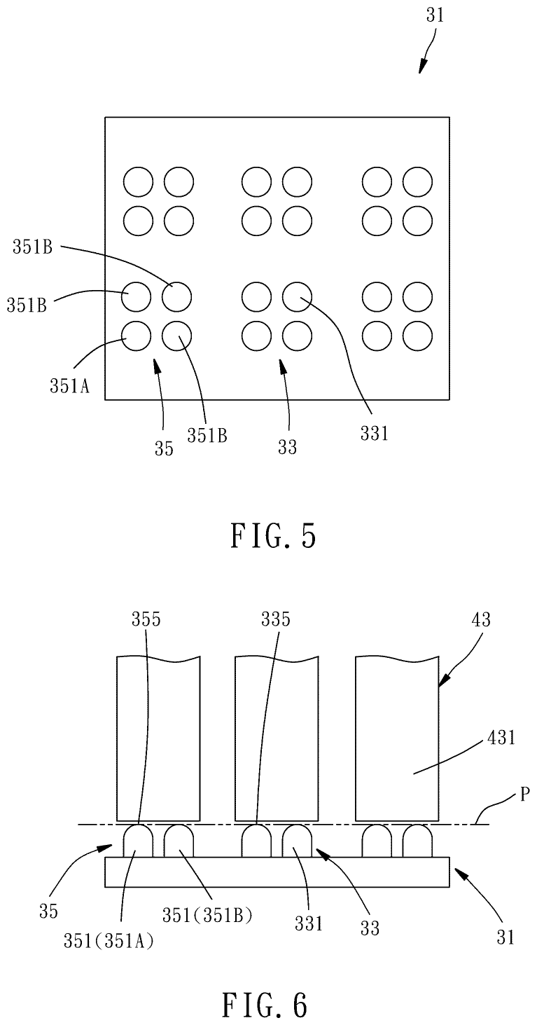

As shown in FIG. 1, the device under test 31 is formed on the wafer 30. For the simplification of the figures and the convenience of illustration, the devices under test 31 are only schematically shown in FIG. 1, but the first and second micro-bumps 331, 351 on the devices under test 31 are not shown in FIG. 1. Besides, only one of the devices under test 31 of the wafer 30 is shown in FIG. 4. The device under test 31 actually has many bump units. In FIG. 4 and FIG. 5, only six bump units are schematically shown, and two of them are the aforementioned first and second bump units 33, 35. The other bump units may be similar to the first bump unit 33 for transmitting the power signal or the ground signal, or may be similar to the second bump unit 35 for transmitting a test signal.

It should be mentioned here that in the present invention the first and second micro-bumps 331, 351 and/or first and second bumps 333, 353 (specified hereinafter) on the device under test 31 may have been formed on the wafer 30 when the manufacture of the wafer 30 is accomplished. Alternatively, a redistribution layer may be further formed on the surface of the wafer 30 after the manufacture of the wafer 30 is accomplished, and the first and second micro-bumps 331, 351 and/or the first and second bumps 333, 353 are arranged on the redistribution layer.
b) Provide the test apparatus 20, as shown in FIG. 1.

In principle, the probe card 22 in the test apparatus 20 provided in the present invention doesn't use hybrid probes, so as to avoid the poor probe planarity problem that may be caused by the different contact force of the probes of different probe types and the resulting different wear loss thereof. Because the body portion 433 makes up a large proportion of the probe 43 in length, the body portion 433 has relatively larger affection on the probe contact force. Therefore, the present invention only confines the body portions 433 of the probes 43 of the probe card 22 to be substantially the same in size. That means the body portions 433 of the probes 43 are substantially the same in structural type, and/or substantially the same in length, width and thickness, and/or substantially the same in cross-sectional area. For example, the probes 43 adopted in this embodiment are substantially the same at least in body portions 433 thereof in all the aspects of structural type, length, width, thickness, and cross-sectional area. In this way, the probes 43 generate substantially the same probe contact force and wear loss. In another embodiment, the probes 43 adopted in the probe card 22 may be all the same. For example, all the probes 43 are substantially the same in structural type, length, width, thickness, and cross-sectional area. In the embodiment shown in FIG. 4, the head portions 431 of the probes 43 are all the same, the same in cross-sectional area and the same in cross-sectional shape, wherein the cross-sectional shape may be a circle or a rectangle.
c) Place the device under test 31 on the chuck 21 of the test apparatus 20, and test the device under test 31 by using the probes 43 of the probe card 22 to contact the device under test 31. During the device under test being tested, the first bump unit 33 is contacted by only one of the probes 43, and the second bump unit 35 is contacted by only another one of the probes 43.

In other words, the bump units arranged on the device under test 31 are configured for all the micro-bumps in a same bump unit to be contacted by a same probe 43, and each probe 43 only contacts a bump unit. In practice, the device under test 31 is arranged thereon with relatively more power micro-bumps and ground micro-bumps, and relatively fewer testing micro-bumps. Therefore, the power micro-bumps or ground micro-bumps are arranged as the above-described first bump unit 33 for a same probe 43 to contact a plurality of first micro-bumps 331 at the same time to provide the power signal or ground signal to the circuits respectively corresponding to the first micro-bumps 331. Because the testing micro-bumps should transmit different test signals respectively, a same probe 43 cannot contact a plurality of testing micro-bumps at the same time. In order to let the testing micro-bumps receive the same probing pressure with the first micro-bumps 331, the second bump unit 35 is arranged in a way that extra micro-bumps, i.e. dummy micro-bumps 315B, are added near the testing micro-bump actually for transmitting the test signal, i.e. the selected micro-bump 351A, for a same probe 43 to contact the selected micro-bump 351A and the dummy micro-bumps 351B at the same time to provide the test signal to the circuit corresponding to the selected micro-bump 351A. In this way, the dummy micro-bumps 351B bear a part of the probe contact force, so that the probing pressure received by the selected micro-bump 351A can be the same with the probing pressure received by the first micro-bump 331. It can be seen that the primary function of the dummy micro-bump 351B is to share the probe contact force with the selected micro-bump 351A, so the dummy micro-bump 351B and the selected micro-bump 351A may be electrically disconnected from each other. In this way, the dummy micro-bump 351B needs not to connect any circuit, which makes the device under test 31 have relatively fewer circuits and thereby relatively easier to design and manufacture. The dummy micro-bump 351B may be substantially the same in size with the selected micro-bump 351A, so that the micro-bumps on the device under test 31 are uniform in size, thereby relatively simpler to design, facilitating the positional arrangement of the micro-bumps, and sharing the probe contact force relatively more evenly, which is beneficial for generating consistent probing performance. Besides, in another embodiment, the second bump unit 35 is arranged in a way that the dummy micro-bump 351B and the selected micro-bump 351A are electrically connected with each other. For example, they may be electrically connected with each other through a trace. In this way, the dummy micro-bump 351B not only bears a part of the probe contact force, but also receives the test signal transmitted from the probe 34. However, the dummy micro-bump 351B is arranged being unable to transmit the test signal out of its belonging second bump unit 35. Therefore, the dummy micro-bump 351B can only transmit the test signal to the selected micro-bump 351A of its belonging second bump unit 35, and then the test signal is transmitted through the selected micro-bump 351A out of its belonging second bump unit 35. That can improve the test signal transmitting stability of the second bump unit 35.

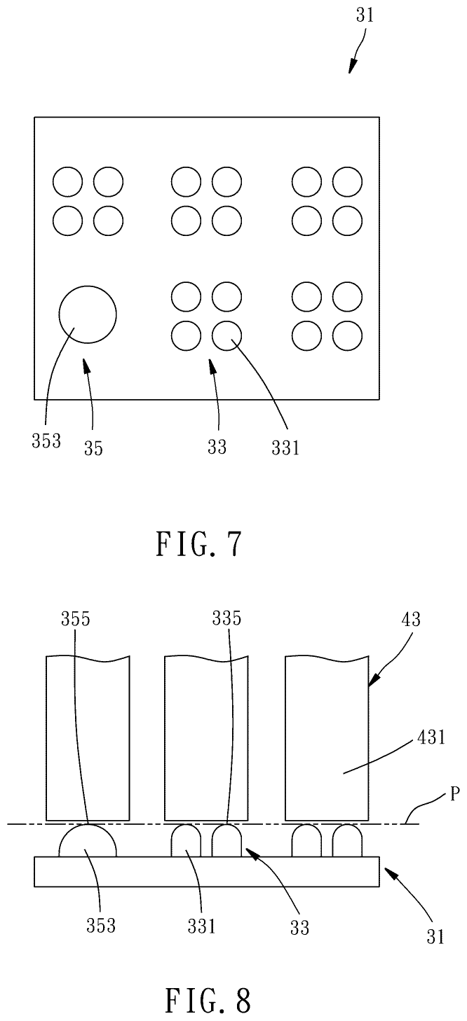

Referring to FIG. 7 and FIG. 8, a second preferred embodiment of the present invention provides another arrangement of the bumps of the device under test 31.

In this embodiment, the device under test 31 is arranged in a way that the first bump unit 33 includes four first micro-bumps 331 grouping together, and the second bump unit 35 only includes a single second bump 353. The area of the second bump 353 is larger than the area of a single first micro-bump 331. The first micro-bumps 331 are all arranged for transmitting the first signal, which means the first micro-bumps 331 transmit the power signal together or transmit the ground signal together. The second bump 353 is arranged for transmitting the second signal, i.e. transmitting the test signal.

In other words, the device under test 31 in this embodiment is similar to the device under test 31 in the first preferred embodiment. However, in the second bump unit 35 in this embodiment, the probe contact force is not shared by adding extra micro-bumps near the testing micro-bump, but the testing micro-bump is replaced by a relatively larger second bump 353, so that the probing pressure received by the second bump 353 can be the same with the probing pressure received by the first micro-bump 331.

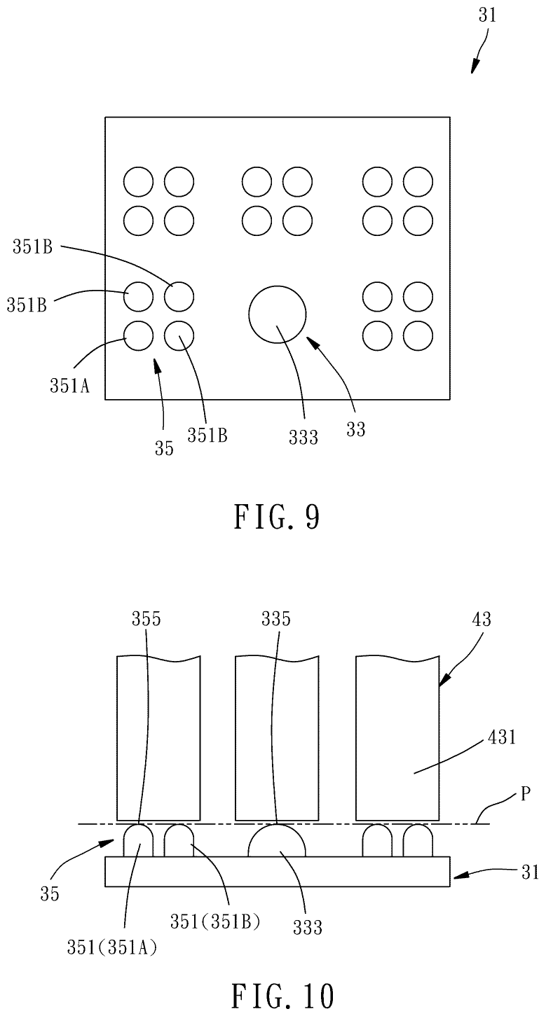

Referring to FIG. 9 and FIG. 10, a third preferred embodiment of the present invention provides still another arrangement of the bumps of the device under test 31.

In this embodiment, the device under test 31 is arranged in a way that the first bump unit 33 only includes a single first bump 333, and the second bump unit 35 includes four second micro-bumps 351 grouping together. The area of the first bump 333 is larger than the area of a single second micro-bump 351. The first bump 333 is arranged for transmitting the first signal, i.e. transmitting the power signal or transmitting the ground signal. The second micro-bumps 351 include at least one selected micro-bump 351A arranged for transmitting the second signal, and at least one dummy micro-bump 351B unable to transmit the second signal out of the second bump unit 35.

In other words, the device under test 31 in this embodiment is similar to the device under test 31 in the first preferred embodiment, but the plurality of first micro-bumps 331 in the first preferred embodiment is replaced by a relatively larger first bump 333 in this embodiment. That means the circuits corresponding to the former plurality of first micro-bumps 331 respectively are all connected with the first bump 333. As long as the first bump 333 is contacted by a probe 43, the circuits can be supplied with the power signal or ground signal. This arrangement can also make the probing pressure received by the second micro-bump 351 the same with the probing pressure received by the first bump 333.

As shown in FIG. 9 and FIG. 10, the first bump unit 33 has a first upper surface 335 for being contacted by the probe 43, that is the top section of the arc surface of the first bump 333. The second bump unit 35 has a second upper surface 355 for being contacted by the probe 43, that is the top section of the arc surface of every second micro-bump 351. The first upper surface 335 and the second upper surface 355 are substantially located on a same horizontal plane P, such that the head portions 431 of the probes 43 will contact the bump and/or micro-bumps required to be contacted thereby at the same time, so as to generate consistent probing performance, and avoid different wear loss between the probes and the resulting poor probe planarity problem. Likewise, in the configurations shown in FIG. 8 and FIG. 6, the first upper surface 335 of the first bump unit 33 and the second upper surface 355 of the second bump unit 35 are also substantially located on a same horizontal plane P, which can also attain the above-described effects.

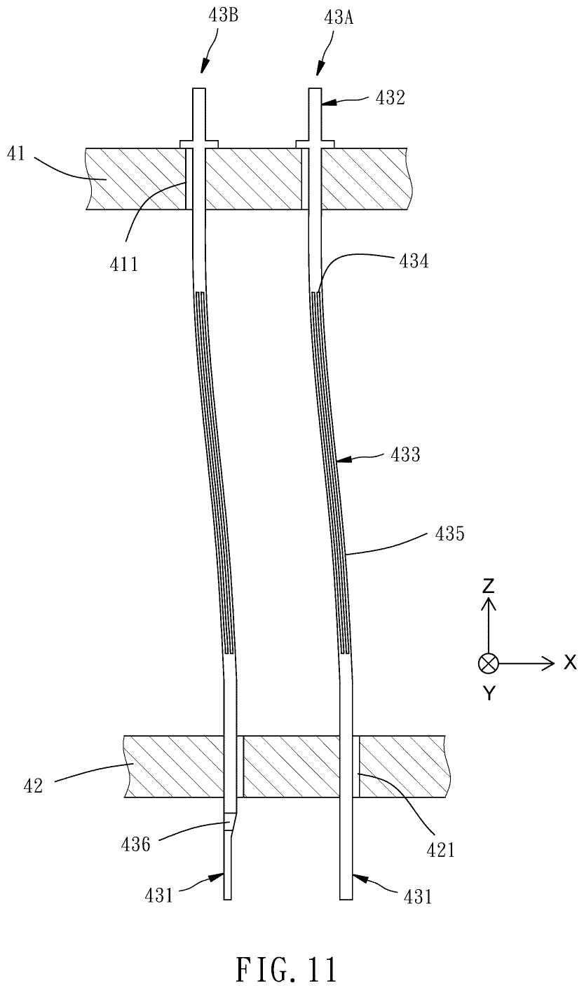

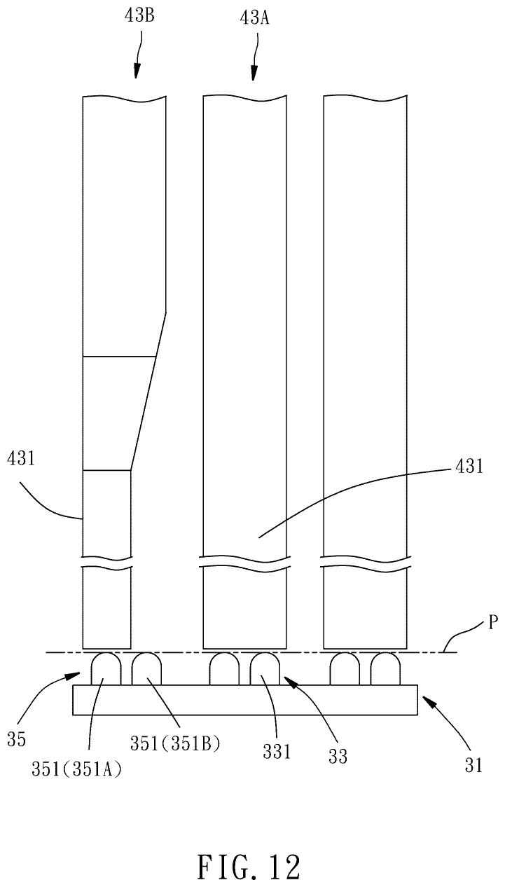

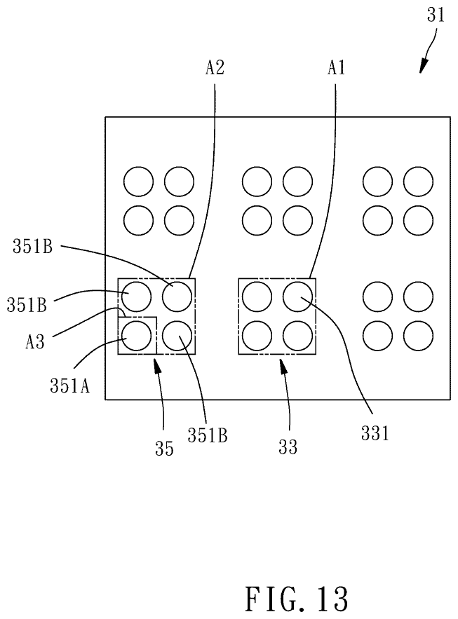

Referring to FIG. 11 to FIG. 13, a fourth preferred embodiment of the present invention provides another probe arrangement. The device under test 31 in this embodiment is the same with that shown in FIG. 5. The plurality of probes in this embodiment have the same tail portions 432 and the same body portions 433, but have differently sized head portions 431.

Specifically speaking, the probes in this embodiment include a first probe 43A for contacting the first bump unit 33, and a second probe 43B for contacting the second bump unit 35. The body portion 433 and the head portion 431 of the first probe 43A are the same in cross-sectional area, and the cross-sectional area thereof equals to the projected area A1 of the head portion 431. The cross-sectional area of the second probe 43B gradually reduce from the body portion 433 to the head portion 431 through a gradually narrowing portion 436, so that the cross-sectional area of the body portion 433 of the second probe 43B, which equals to the projected area A2 of the body portion 433, is larger than the cross-sectional area of the head portion 431, which equals to the projected area A3 of the head portion 431. It can be seen in FIG. 11 to FIG. 13 that the body portions 433 of the first and second probes 43A, 43B and the head portion 431 of the first probe 43A are all the same in cross-sectional area, and their projected areas A1, A2 each cover four micro-bumps. However, the head portion 431 of the second probe 43B has relatively smaller cross-sectional area, and the projected area A3 thereof covers only one micro-bump. During the device under test being tested, the head portion 431 of the first probe 43A contacts all the first micro-bumps 331 of the first bump unit 33 at the same time, and the head portion 431 of the second probe 43B contacts only one second micro-bump, i.e. the selected micro-bump 351A.

In other words, the probes in the present invention, under the condition that the body portions 433 thereof are substantially the same in size, may still have differently sized head portions 431, and the first and second probes 43A, 43B can still generate substantially the same probe contact force, thereby substantially the same in wear loss, so as to avoid the poor probe planarity problem. Besides, even though the head portions 431 of the first and second probes 43A, 43B contact different amounts of micro-bumps, the second bump unit 35 can be still arranged in a way that the second micro-bumps 351 thereof are all included in the projected area A2 of the body portion 433 of the second probe 43B, so that the projected areas A1, A2 of the body portions 433 of the first and second probes 43A, 43B still correspond to the same amount of micro-bumps. Therefore, the arrangement of the second micro-bumps 351 can be the same with the arrangement of the first micro-bumps 331, such that the micro-bumps of the device under test 31 still maintain a neat arrangement, such as being arranged in a matrix. In this way, the design of the micro-bumps of the device under test 31 is simple and uniform.

As shown in FIG. 11, the body portion 433 of the probe in this embodiment includes two slots 434. The slot 434 extends into an elongated shape along the longitudinal direction of the body portion 433. That is, when the body portion 433 has not been curved yet, the slot 434 extends along a vertical axis (Z-axis). Besides, the slot 434 penetrates through the body portion 433 along a first horizontal axis (Y-axis) so that the body portion 433 is defined with three thin pieces of arm sections 435 by the two slots 434. The three arm sections 435 are separated from each other along a second horizontal axis (X-axis). Such slot 434 can weaken the rigidity of the body portion 433, so as to lower the probe contact force, thereby preventing the probe contact force from being so larger as to damage the micro-bumps of the device under test 31. In addition, the body portion 433 originally extends in a straight line along the Z-axis, and the body portion 433 is curved along the X-axis into the state as shown in FIG. 11 when the upper and lower die units 41, 42 are offset along the X-axis. When the head portion 431 contacts the device under test 31 and thereby receives a force, the body portion 433 can be further elastically curved along the X-axis. The above-described slot 434 can improve the elasticity of the body portion 433 being curved along the X-axis, thereby ensuring the elastically deformed effect of the body portion 433 being curved along the X-axis.

In conclusion, the present invention provides the testing method, the probe system 10 and the device under test 31 for the micro-bump test, wherein the bumps and/or micro-bumps on the device under test 31 are arranged for each probe 43 of the probe card 22 to contact a plurality of micro-bumps or a single relatively larger bump. As a result, the probe card 22 can be arranged with relatively fewer probes 43, and the probes 43 can be provided therebetween with relatively larger pitch. Therefore, the difficulty of manufacturing the probe card 22, the cost of the probe card 22 and the difficulty of using the probe card 22 on the machine for testing are relatively lower, and the design of the device under test 31 is not too complicated. Besides, the probes 43 adopted in the probe card 22 can be all substantially the same. In other words, the probe card 22 can avoid using hybrid probes, thereby prevented from the poor probe planarity problem that may be caused by difference in wear loss between the probes of different probe types.

The invention being thus described, it will be obvious that the same may be varied in many ways. Such variations are not to be regarded as a departure from the scope of the invention, and all such modifications as would be obvious to one skilled in the art are intended to be included within the scope of the following claims.

What is claimed is:

1. A testing method for a micro-bump test, which uses a probe card in a probe system to test a device under test having a plurality of micro-bumps, the testing method comprising the steps of:
providing the device under test, the device under test comprising a first bump unit for transmitting a first signal and a second bump unit for transmitting a second signal, the first signal being one of a power signal and a ground signal, the second signal being a test signal different from the power signal and the ground signal, the device under test having one of three following arrangements that:
the device under test is configured in a way that the first bump unit comprises a plurality of first micro-bumps grouping together, the second bump unit comprises a plurality of second micro-bumps grouping together, an amount of the first micro-bumps of the first bump unit is the same with an amount of the second micro-bumps of the second bump unit, the first micro-bumps are all arranged for transmitting the first signal, and the second micro-bumps comprise at least one selected micro-bump arranged for transmitting the second signal and at least one dummy micro-bump unable to transmit the second signal out of the second bump unit;
the device under test is configured in a way that the first bump unit comprises a plurality of first micro-bumps grouping together, the second bump unit only comprises a single second bump, an area of the second bump is larger than an area of a single one of the first micro-bumps, the first micro-bumps are all arranged for transmitting the first signal, and the second bump is arranged for transmitting the second signal; and
the device under test is configured in a way that the first bump unit only comprises a single first bump, the second bump unit comprises a plurality of second micro-bumps grouping together, an area of the first bump is larger than an area of a single one of the second micro-bumps, the first bump is arranged for transmitting the first signal, and the second micro-bumps comprise at least one selected micro-bump arranged for transmitting the second signal and at least one dummy micro-bump unable to transmit the second signal out of the second bump unit;
providing a test apparatus, the test apparatus comprising a chuck and the probe card, the probe card comprising a plurality of probes, each of the probes comprising a head portion located at an end of the probe for contacting the device under test, a tail portion located at the other end of the probe, and a body portion located between the head portion and the tail portion, the body portions of the probes being substantially the same in size; and
placing the device under test on the chuck of the test apparatus, and testing the device under test by using the probes of the probe card to contact the device under test, wherein during the device under test being tested, the first bump unit is contacted by only one of the probes, and the second bump unit is contacted by only another one of the probes.

2. The testing method as claimed in claim 1, wherein the head portions of the probes have a substantially same cross-sectional area.

3. The testing method as claimed in claim 1, wherein each of the probes is one of a straight probe and a buckling probe.

4. The testing method as claimed in claim 1, wherein the device under test is configured in a way that when the first bump unit and the second bump unit are contacted by the head portions of the probes, the first bump unit and the second bump unit receive a substantially same probing pressure.

5. The testing method as claimed in claim 1, wherein the first bump unit has a first upper surface for being contacted by the probe of the probe card; the second bump unit has a second upper surface for being contacted by the probe of the probe card; the first upper surface and the second upper surface are substantially located on a same horizontal plane.

6. The testing method as claimed in claim 1, wherein the dummy micro-bump and the selected micro-bump of the second bump unit are substantially the same in size.

7. The testing method as claimed in claim 1, wherein the dummy micro-bump and the selected micro-bump of the second bump unit are electrically disconnected from each other.

8. The testing method as claimed in claim 1, wherein the probes of the probe card are arranged in a way that when contacting the device under test to test the device under test, the probes provide a substantially same probe contact force.

9. The testing method as claimed in claim 1, wherein the head portions of the probes have substantially a same cross-sectional shape.

10. The testing method as claimed in claim 9, wherein the cross-sectional shape of the head portions of the probes is one of a circle and a rectangle.

11. The testing method as claimed in claim 1, wherein the body portion of the probe comprises at least one slot; the slot penetrates through the body portion along a first horizontal axis so that the body portion is defined with at least two arm sections by the at least one slot; the at least two arm sections are separated from each other along a second horizontal axis; the body portion is curved along the second horizontal axis.

12. The testing method as claimed in claim 1, wherein the probes comprise a first probe and a second probe; a cross-sectional area of the head portion of the second probe is smaller than a cross-sectional area of the head portion of the first probe; during the device under test being tested, the head portion of the first probe contacts said plurality of first micro-bumps at the same time, and the head portion of the second probe contacts only one said second micro-bump.

13. The testing method as claimed in claim 12, wherein a projected area of the body portion of the second probe covers said plurality of second micro-bumps.

14. A device under test for a micro-bump test, the device under test comprising a first bump unit for transmitting a first signal and a second bump unit for transmitting a second signal, the first signal being one of a power signal and a ground signal, the second signal being a test signal different from the power signal and the ground signal, the device under test having one of three following arrangements that:
the device under test is configured in a way that the first bump unit comprises a plurality of first micro-bumps grouping together, the second bump unit comprises a plurality of second micro-bumps grouping together, an amount of the first micro-bumps of the first bump unit is the same with an amount of the second micro-bumps of the second bump unit, the first micro-bumps are all arranged for transmitting the first signal, and the second micro-bumps comprise at least one selected micro-bump arranged for transmitting the second signal and at least one dummy micro-bump unable to transmit the second signal out of the second bump unit;
the device under test is configured in a way that the first bump unit comprises a plurality of first micro-bumps grouping together, the second bump unit only comprises a single second bump, an area of the second bump is larger than an area of a single one of the first micro-bumps, the first micro-bumps are all arranged for transmitting the first signal, and the second bump is arranged for transmitting the second signal; and
the device under test is configured in a way that the first bump unit only comprises a single first bump, the second bump unit comprises a plurality of second micro-bumps grouping together, an area of the first bump is larger than an area of a single one of the second micro-bumps, the first bump is arranged for transmitting the first signal, and the second micro-bumps comprise at least one selected micro-bump arranged for transmitting the second signal and at least one dummy micro-bump unable to transmit the second signal out of the second bump unit.

15. The device under test as claimed in claim 14, wherein said plurality of first micro-bumps are four said first micro-bumps arranged in a 2×2 array; said plurality of second micro-bumps are four said second micro-bumps arranged in a 2×2 array.

16. The device under test as claimed in claim 14, wherein the dummy micro-bump and the selected micro-bump of the second bump unit are substantially the same in size.

17. The device under test as claimed in claim 14, wherein the dummy micro-bump and the selected micro-bump of the second bump unit are electrically disconnected from each other.

18. The device under test as claimed in claim 14, wherein the device under test is configured to be contacted by a probe card for being tested; the probe card comprises a plurality of probes; each of the probes comprises a head portion located at an end of the probe for contacting the device under test, a tail portion located at the other end of the probe, and a body portion located between the head portion and the tail portion; the body portions of the probes are substantially the same in size; the device under test is arranged in a way that when the first bump unit and the second bump unit are contacted by the head portions of the probes, the first bump unit and the second bump unit receive a same probing pressure.

19. The device under test as claimed in claim 14, wherein the first bump unit has a first upper surface for being contacted by a probe of a probe card; the second bump unit has a second upper surface for being contacted by another probe of the probe card; the first upper surface and the second upper surface are substantially located on a same horizontal plane.

20. A probe card for a micro-bump test, which is applied in a probe system to test a device under test having a plurality of micro-bumps, the probe card comprising:
a main circuit board;
a space transformer; and
a probe head, the probe head and the main circuit board being disposed on two opposite sides of the space transformer, the probe head comprising at least one die unit and a plurality of probes, the die unit being provided with a plurality of guiding holes, the probes being slidably inserted in the guiding holes, each of the probes comprising a head portion located at an end of the probe for contacting the device under test, a tail portion located at the other end of the probe, and a body portion located between the head portion and the tail portion, the body portions of the probes being substantially the same in size, the tail portions of the probes being electrically connected to the space transformer;
wherein the device under test is the device under test as claimed in claim 14; when the device under test is tested by the probe card, the device under test is placed on a chuck of the probe system, the first bump unit is contacted by only one of the probes, and the second bump unit is contacted by only another one of the probes.

21. A probe system for a micro-bump test, which is configured to test a device under test having a plurality of micro-bumps, the probe system comprising:
a chuck configured to support the device under test;
the probe card as claimed in claim 20;
an imaging device configured to collect an optical image of at least a region of the probe system; and
a signal generation and analysis device configured for at least one of supplying a test signal to the device under test and receiving a resultant signal from the device under test.

22. The probe system as claimed in claim 21, wherein the head portions of the probes have a substantially same cross-sectional area.

23. The probe system as claimed in claim 21, wherein each of the probes is one of a straight probe and a buckling probe.

24. The probe system as claimed in claim 21, wherein the device under test is configured in a way that when the first bump unit and the second bump unit are contacted by the head portions of the probes, the first bump unit and the second bump unit receive a substantially same probing pressure.

25. The probe system as claimed in claim 21, wherein the first bump unit has a first upper surface for being contacted by the probe of the probe card; the second bump unit has a second upper surface for being contacted by the probe of the probe card; the first upper surface and the second upper surface are substantially located on a substantially same horizontal plane.

26. The probe system as claimed in claim 21, wherein the probes of the probe card are arranged in a way that when contacting the device under test to test the device under test, the probes provide a substantially same probe contact force.

27. The probe system as claimed in claim 21, wherein the head portions of the probes have a substantially same cross-sectional shape.

28. The probe system as claimed in claim 27, wherein the cross-sectional shape of the head portions of the probes is one of a circle and a rectangle.
